(19) United States
(12) Patent Application Publication
(10) Pub. No.: US 2007/0252252 A1
(43) Pub. Date: Nov. 1, 2007

(54) Structure of electronic package and printed circuit board thereof

(75) Inventor: Wen-Jeng Fan, Hukou (TW)

Correspondence Address: BIRCH STEWART KOLASCH & BIRCH, PO BOX 747, FALLS CHURCH, VA, 22040-0747, US

(73) Assignee: Powertech Technology Inc.

(21) Appl. No.: 11/413,014

(22) Filed: Apr. 28, 2006

(51) Int. Cl. H01L 23/02

(52) U.S. Cl. 257/678

(57) ABSTRACT

A PCB for mounting IC package is designed with dummy solder pads. Dummy solder pastes will spread on the dummy solder pads after screen printing process of solder paste. A substrate for a package of IC is designed with or without dummy solder pads. After mounting the package of IC onto the PCB, the dummy solder paste may or may not solder to the substrate of the package of IC. When the package of IC suffers external force, the dummy solder pastes can help provide supporting for the package of IC and increase the mechanical strength to avoid package or IC crack.

### BACKGROUND OF THE INVENTION

1. Field of the Invention

The present invention relates to a PCB (Printed Circuit Board) applied to the structure of electronic package, and more especially, to the structure of memory IC device package and memory modules.

2. Description of the Related Art

According to the high speed developing of semiconductor industries, IC component designs of electronic devices tend to develop on high pin counts and multi-functional requirement. Nowadays, the component outline design will prefer thin, small, short, and light. For these reasons, the assembly process faces lots of challenge, for example, the trace patterns design becomes more and more complex, high requirements on electrical, thermal and reliability performance, package materials selection, warpage control, and the issue of mechanical strength. These are the problems that assembly industries meet currently.

FIG. 1 is the top-view diagram illustrating the current DDR2 SDRAM memory module. One or more Ball Grid Array (BGA) memory ICs 200 are assembled on a PCB 100 by SMT technology. A plurality of metal connectors 300 (gold finger) are configured on the edge of PCB 100 to electrically connect related motherboard or devices. Most of electronic devices have memory modules therein. One assembler will process the memory modules insertion operation in an assembly, that is, to insert the metal connectors 300 into the slot of motherboard (not shown). Furthermore, end user will purchase one memory module and install it by himself or herself to increase memory capacity. As this result, inappropriate force will cause IC package deformed and damage the die during the insert operation.

FIG. 2 is a portion of cross-sectional diagram illustrating the PCB with BGA packages according to the related art. Simply, memory IC 200 uses metal solder balls 230 as input and output connectors for the IC device via array distribution method to connect PCB 100. Then traditional surface mount technology (solder paste printing, pick and placement, and reflow process, etc), are executed to connect with other PCB or substrate. On application, shown in FIG. 2, when consumers and assemblers insert memory modules into other devices, inappropriate force on the corner of package will damage both the structure and the IC more easily. The lifetime of IC will decrease. So how to improve the mechanical strength efficiently and protect the IC component inside the package is very important because it relates to the reliability and lifetime of the IC device.

### SUMMARY OF THE INVENTION

In order to solve above issue, one of objects of the present invention provides a structure of package and the PCB applied thereto. The PCB has a plurality of dummy pads on the sides or corners according to the package outline, and dummy solder pastes are spread at the dummy pads. The package carrier, substrate, may have dummy pad at edge or corners in accordance with the location of dummy pads on PCB. The dummy pads of substrate will connect to PCB after surface mounting process to provide supporting against exterior force and reduce the deformation of the structure of the package. For substrate without dummy pad design, the package will be support by dummy pastes of PCB when external forces are applied. This still can reduce the package deformation.

Another one of objects of the present invention is to provide a structure of package and the PCB applied thereto. The dummy pads arranged on a PCB or a substrate or both may be implemented without the additional consumption of process and cost.

Accordingly, one embodiment of the present invention is to provide a carrier (substrate) for a package structure and the PCB The substrate or PCB has a first surface, a second surface including a region of conductive connection and a region of non-conductive connection surrounding the region of conductive connection. A plurality of dummy pads are distributed within the region of non-conductive connection.

### BRIEF DESCRIPTION OF THE DRAWINGS

FIG. 1 is a top view diagram illustrating conventional DDR2 memory module in accordance with one prior art;

FIG. 2 is a portion of cross-view diagram illustrating a BGA package assembled on a printed circuit board in accordance with one prior art;

FIG. 3 is a portion of side-view diagram illustrating a package of IC assembled on a printed circuit board in accordance with one embodiment of the present invention;

FIG. 4 is a scaled-up portion of layout of PCB for the package of IC in accordance with one embodiment of the present invention;

FIGS. 5A, 5B, 5C, and 5D are scaled-up portion of the PCB in accordance with the embodiment of the present invention;

FIG. 6 is a portion of side-view diagram illustrating a package of IC assembled on a printed circuit board in accordance with one embodiment of the present invention; and

FIG. 7 is a scaled-up portion of layout of substrate for the package of IC in accordance with one embodiment of the present invention.

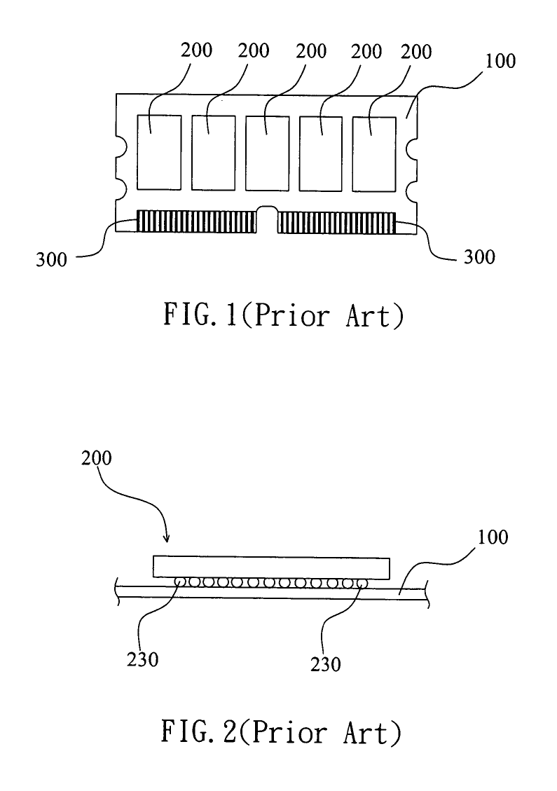

### DETAILED DESCRIPTION OF THE INVENTION

The embodiments of the present invention are illustrated in reference to the drawings.

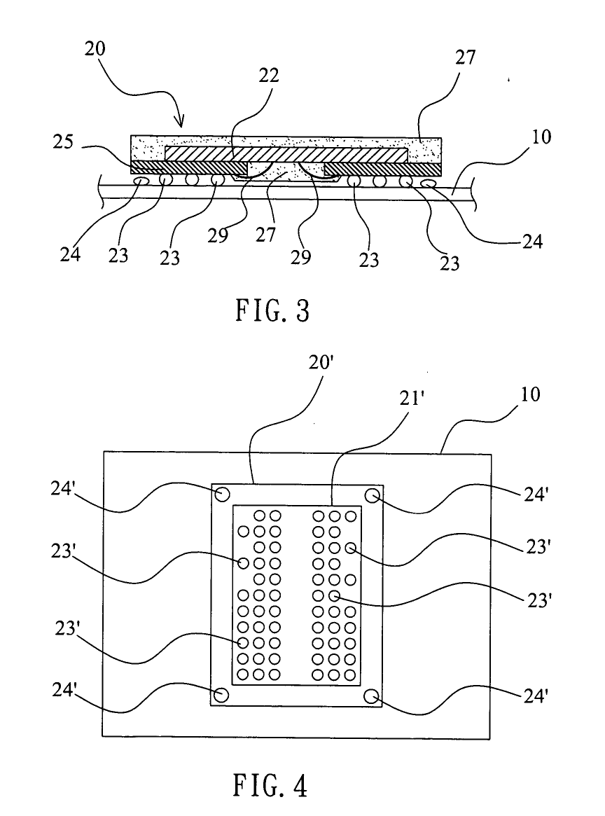

FIG. 3 is a portion of side-view schematic diagram illustrating a package of IC assembled on a printed circuit board (PCB). Shown in FIG. 3, an exterior element, such as a package of IC 20 is assembled on one surface of a printed circuit board (PCB) 10. In the embodiment, the package of IC 20 is a window BGA, but not limited to.

Next, a chip 22 is fixed or attached on one surface of a substrate 25 with a die-attached material (not shown). In the embodiment, the substrate 25 is with a window path which a plurality of structures of conductive connection 29 are electrically connected the chip 22 and the substrate 25. A molding compound 27 covers the chip 22 and the structures of conductive connection 29 to make the package of IC 20. The package of IC 20 may include a plurality of conductive balls 23 that are attached to and electrically connected to the printed circuit board 10. A plurality of dummy solder pastes 24 are distributed on the sides or corners of the PCB according to the outline of the package of IC. In one embodiment, the solder pastes 24 are attached onto the dummy pads of the PCB 10.

Next, FIG. 4 is a scaled-up portion diagram illustrating a layout of PCB in accordance with one embodiment of the present invention. The surface of the PCB 10 has a region of conductive connection 21′ and a region of non-conductive connection 20′ surrounding the region of conductive connection 21′. The region of conductive connection 21′ includes a plurality of positions 23′ for the conductive pads and the region of non-conductive connection 20′ includes a plurality of positions 24′ of dummy pads distributed near the peripheral region of the outline of the package of IC. Alternatively, the positions 24′ of dummy pads may be designed on the surface of the substrate 25 in FIG. 3. Alternatively, the positions 24′ of dummy pads may be designed on the both surfaces of the substrate 25 or the PCB 10 that will be connected with the metal balls.

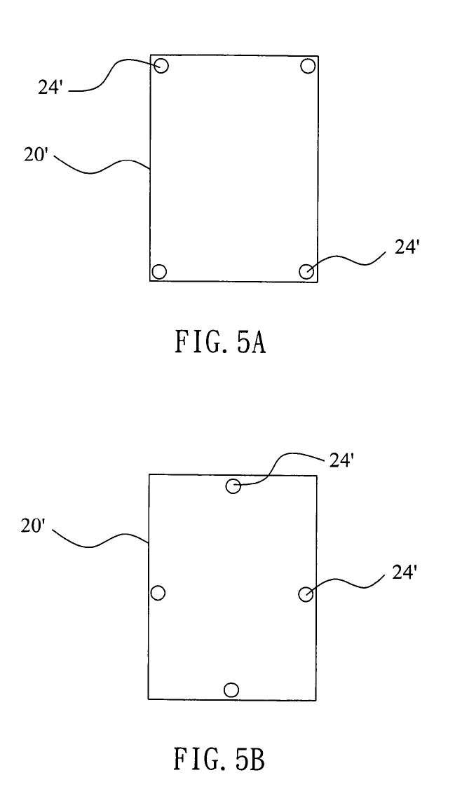

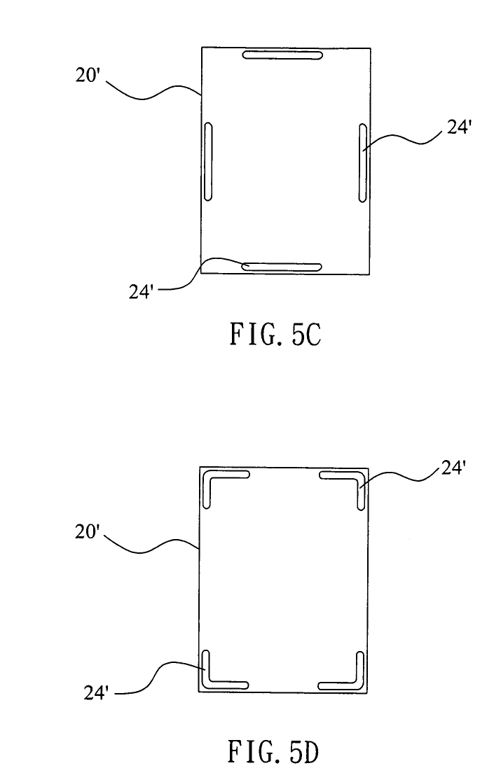

FIGS. 5A, 5B, 5C, and 5D are scaled-up portion of the PCB or the substrate in accordance with the embodiment of the present invention. The positions 24′ of dummy pads are distributed on the corners or sides of the region of non-conductive connection 20′ of the PCB. The dummy pads may be designed round-shaped, oval-shaped, poly-arc or polygon-shaped, or bar-shaped. The dummy solder pastes by screen-printing method may be round-shaped, oval-shaped, polyhedron-shaped, or bar-shaped.

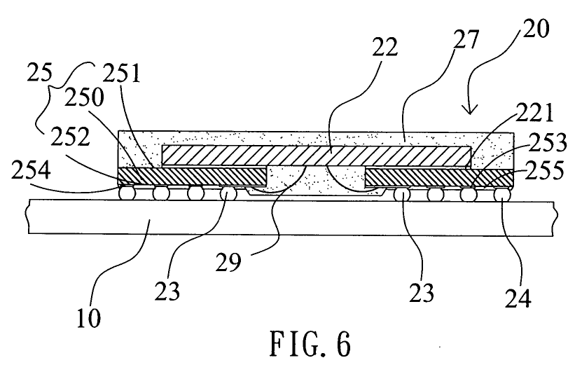

Alternatively, FIG. 6 is a portion of side-view schematic diagram illustrating a package of IC assembled on a printed circuit board. Shown in FIG. 6, a package of IC 20 is assembled on one surface of a printed circuit board 10. In the embodiment, the package of IC 20 is a window BGA, but not limited to. The type of Ball Grid Array (BGA), Fine pitch Ball Grid Array (FBGA), Very Fine pitch Ball Grid Array (VFBGA), or micro Ball Grid Array (PBGA) may be used in the present invention.

Next, a chip 22 is fixed on a first surface 251 of a substrate 25 with a die-attached material 221. In the embodiment, the substrate 25 is one with a bulk 250 having a window through the first surface 251 and a second surface 252. Next, a plurality of structures of conductive connection 29 via the window, such as conductive wires, are electrically connected the chip 22 and conductive pads 253 on the second surface 252. Alternatively, the structures of conductive connection 29 may be electrically connected the chip 22 to the first surface 251 of the substrate 25. Furthermore, a plurality of dummy pads 254 on the second surface 252 may be distributed around the conductive pads 253. A passivation layer 255, such as a solder resist covering the second surface 252 but exposed the conductive pads 253 and dummy pads 254. Next, a molding compound 27 is covered the chip 22, the first surface 251 of the substrate 25 and the structures of conductive connection 29. The package of IC 20 may include a plurality of conductive balls 23 that are respectively corresponding to the conductive pads 253 on the second surface 252 of the substrate 25, fixed and electrically connected to the printed circuit board 10.

Next, a plurality of dummy solder pastes 24 formed by a screen-printing method is attached on the surface of the printed circuit board 10. The dummy solder pastes 24 may be corresponding attached to the dummy pads 254 with surface mounting technology. In the embodiment, the whole heights of dummy solder pastes 24 connected the dummy pads 254 are no larger than the standoff height between the package of IC 20 and the printed circuit board 10, such as the height of attached metal balls, to ensure conductive balls soldered on the printed circuit board.

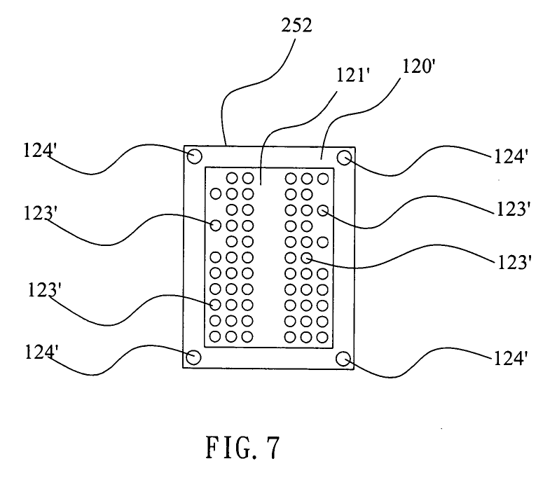

FIG. 7 is a scaled-up portion diagram illustrating a layout of substrate for a package in accordance with one embodiment of the present invention. The second surface 252 of the substrate 25 has a region of conductive connection 121′ and a region of non-conductive connection 120′ surrounding the region of conductive connection 121′. The region of conductive connection 121′ includes a plurality of positions 123′ for the conductive pads and the region of non-conductive connection 120′ includes a plurality of positions 124′ of dummy pads distributed near the peripheral region of the substrate 25, that is a perimeter of the region of conductive connection 121′. The non-conductive connection area may or may not include the dummy pads. It is noted that the layout of dummy pads on the substrate 25 is similar to the one on the printed circuit board 10, but not limited to.

Although the present invention has been explained in relation to its preferred embodiment, it is to be understood that other modifications and variation can be made without departing the spirit and scope of the invention as hereafter claimed.

What is claimed is:

1. A printed circuit board (PCB) used for an IC package mounting, comprising:
a first surface; and
a second surface including a region of conductive connection and a region of non-conductive connection surrounding said region of conductive connection, wherein a plurality of dummy pads are distributed within said region of non-conductive connection.

2. The printed circuit board according to claim 1, wherein said printed circuit board is electrically connected ball grid array package through a plurality of conductive balls affixed to said region of conductive connection.

3. The printed circuit board according to claim 2, further comprising a plurality of dummy solder pastes on said plurality of dummy pads.

4. The printed circuit board according to claim 3, wherein the height of said dummy solder pastes is no larger than the standoff height between said printed circuit board and said substrate of ball grid array package.

5. The printed circuit board according to claim 1, further comprising a passivation layer covering said second surface but exposing said dummy pads.

6. The printed circuit board according to claim 1, wherein a plurality of conductive pads are within said region of conductive connection.

7. A structure of IC package, comprising:
a substrate with a first surface and a second surface opposite thereto;
a chip fixed on said first surface;
a molding compound covering said chip and said first surface; and
a plurality of dummy pads distributed on said second surface and near a perimeter of said substrate.

8. The structure of IC package according to claim 7, further comprising a plurality of conductive pads distributed on said second surface and away from said perimeter of said substrate.

9. The structure of IC package according to claim 8, wherein a portion of said conductive pads are electrically connected said chip.

10. The structure of IC package according to claim 8, further comprising a plurality of conductive solder balls fixed on said conductive pads, respectively.

11. A printed circuit board module, comprising:
a printed circuit board having a first surface with a region of conductive connection, wherein a plurality of conductive pads are distributed within said region of conductive connection;
an external element with a plurality of conductive pads for fixing and electrically connecting said printed circuit board; and
a plurality of first dummy pads on first surface of PCB distributed on a perimeter of said region of conductive connection and within a dimension of said external element.

12. The printed circuit board module, according to claim 11, further comprising a plurality of dummy solder pastes on said first dummy pads of said first surface of PCB.

13. The printed circuit board module according to claim 12, wherein said dummy solder pastes are made by screen-printing method.

14. The printed circuit board module according to claim 11, wherein said external element is characteristic as fine pitch ball grid array, very fine pitch ball grid array, micro ball grid array, or window ball grid array.

15. The printed circuit board module according to claim 11, wherein said first dummy pads are round-shaped, oval-shaped, polygon-shaped, or bar-shaped.

16. The printed circuit board module according to claim 11, wherein said external element comprises:
a substrate;
a chip attached on one surface of said substrate; and
a molding material covering said substrate and said chip.

17. The printed circuit board module according to claim 11, wherein said second dummy pads are electrically connected to a plurality of dummy solder pastes on said first dummy pads.
